(19) United States
(12) Patent Application Publication
(10) Pub. No.: US 2015/0042400 A1
(43) Pub. Date: Feb. 12, 2015

(54) SYSTEMS AND METHODS FOR INTEGRATED VOLTAGE REGULATORS

(71) Applicant: The Trustees of Columbia University in the City of New York, New York, NY (US)

(72) Inventors: Noah Andrew Sturcken, New York, NY (US); Kenneth L. Shepard, New York, NY (US)

(73) Assignee: The Trustees of Columbia University in the City of New York, New York, NY (US)

(21) Appl. No.: 14/333,427

(22) Filed: Jul. 16, 2014

Related U.S. Application Data
(63) Continuation of application No. PCT/US13/22145, filed on Jan. 18, 2013.
(60) Provisional application No. 61/588,045, filed on Jan. 18, 2012.

(51) Int. Cl. G05F 1/46; H01L 21/768

(52) U.S. Cl. CPC G05F 1/465; H01L 21/76898; H01L 21/76879
USPC 327/540; 438/3

(57) ABSTRACT

A multi-chip module (MCM) is disclosed, which in some embodiments can include a packaging substrate, an interposer coupled to the substrate and having a power converter coupled to one or more vias, and a CMOS integrated circuit comprising one or more connecters aligned with and disposed proximate to the one or more vias to electrically couple the interposer to the integrated circuit. Methods of forming a voltage regulator on an interposer of a multi-chip module (MCM) are also provided.

### CROSS-REFERENCE TO RELATED APPLICATIONS

This application is a continuation of International Application No. PCT/US13/022145, filed on Jan. 18, 2013, which claims priority to U.S. Provisional Patent Application Ser. No. 61/588,045, filed on Jan. 18, 2012 each of which is incorporated by reference herein in its entirety.

### STATEMENT REGARDING FEDERALLY-SPONSORED RESEARCH

This invention was made with government support from the U.S. Department of Energy under Grant No. DE-EE002892 and the National Science Foundation under Grant No. EECS-0903466. The government has certain rights in the Invention.

### BACKGROUND

The disclosed subject matter relates to systems and methods for integrated voltage regulators.

Moore's law predicts that the number of on-chip devices per unit area will double every one to two years. 3D chip stacking can contribute to this predicted increase of component density. 3D chip stacking can include vertically integrating various planar components by aligning and bonding them together. Signals and power can be communicated laterally using traditional leads, and vertically using thru-silicon-vias (TSVs). The use of TSVs can result in shorter lead lengths and lower losses than monolithic structures.

Power delivery implementations can employ off-chip, board-level voltage regulator (VR) integrated circuits (along with board level passives) to down-convert independent supply voltages, which can distributed to a processor through board interconnect and IC packaging. Delivering several supply voltages in this manner can involve multiple external VR modules, and such an implementation can be limited by interconnects, both in the distribution of a number of supplies and in losses associated with moving currents over long interconnect distances. Likewise, the switching frequencies of board-level VRs can extend supply voltage transition periods to microseconds, while interconnect impedance between board VR and processor can reduce the regulator's ability to suppress voltage droop during load current transients. As such, power delivery techniques based on discrete, board-level VRs can be inadequate to support the type of active power management required of certain computing devices.

### SUMMARY

Systems and methods for integrated voltage regulators are provided herein.

According to one aspect of the disclosed subject matter, multi-chip modules (MCM) are provided. In an exemplary embodiment, the MCM includes a packaging substrate, an interposer coupled to the substrate and having a voltage regulator coupled to one or more vias, and a CMOS integrated circuit having one or more connecters aligned with and disposed proximate to the one or more vias to electrically couple the interposer to the integrated circuit.

In some embodiments, the voltage regulator can include one or more inductors. The one or more inductors can include multiple inductors, and each inductor can be coupled to one or more inductors proximate thereto. The inductors can include an outer inductor joining a first end inductor to a second end inductor to symmetrically couple each inductor with a pair of neighboring inductors.

In some embodiments, the inductors can be configured as four uncoupled two-turn inductors. Alternatively, the inductors can be configured as eight single-turn coupled inductors. As a further alternative, the inductors can be configured as eight two-turn coupled inductors. As yet another alternative, the inductors can be configured as two sets of four single-turn coupled inductors.

In some embodiments, the voltage regulator can include a buck converter coupled to the one or more inductors and configured to provide a current to inversely couple the one or more inductors. The buck converter can be a multi-phase buck converter, and the MCM can further include a power controller configured to provide power from the buck converter at a different phase corresponding to each of the one or more inductors.

In some embodiments, the interposer can include silicon.

According to another aspect of the disclosed subject matter, methods for forming a voltage regulator on an interposer of a multi-chip module (MCM) are provided. In an exemplarily embedment, a method includes depositing on the interposer a magnetic alloy under a magnetic biasing field to form a plurality of magnetic cores including a top core and a bottom core, inverse coupling adjacent magnetic cores of the plurality of magnetic cores, forming copper windings about each of the plurality of magnetic cores, forming one or more electrodes on the top magnetic core and on the bottom magnetic core, electrically isolating the copper windings from the bottom magnetic core using a layer of barrier material, electrically isolating the copper windings from the top magnetic core using a resist process, joining the electrodes of bottom magnetic core and the top magnetic core to one or more respective pads on the interposer, and forming vias through the interposer proximate the one or more pads.

In some embodiments, the method can include wrapping an outer core around a first end magnetic core and a second end magnetic core to symmetrically couple each magnetic core with a pair of neighboring magnetic cores. The method can further include depositing top and bottom yokes corresponding to each magnetic core by electroplating, and in some embodiments, depositing the top and bottom yokes can include plating the top and bottom yokes through photoresist-defined molds by through-mask plating.

In some embodiments, the method can further include plating an area around each of the top and bottom yokes and separating each plated area with a resist frame. Plating the top and bottom yokes can include applying a magnetic field along an axis of the top and bottom yokes to define a magnetic anisotropy of the top and bottom yokes.

In some embodiments, the method can further include encapsulating the top and bottom yokes with a layer of dielectric material. Forming the vias can include opening a portion of the interposer proximate a point of contact of each top yoke with a corresponding bottom yoke by reactive ion etching. Forming the copper windings can include electroplating the copper windings through a resist mask.

### BRIEF DESCRIPTION OF THE DRAWINGS

FIG. 1 is a diagram illustrating an exemplary integrated voltage regulator (IVR) chip stack.

FIG. 2A is a plan view illustrating four exemplary single-turn, coupled power inductors.

FIG. 2B is a cross-section illustrating exemplary magnetic cores and windings.

FIG. 2C is a diagram illustrating magnetization curves for the inductors of FIG. 2B.

FIGS. 3A-B are cross-sectional views illustrating the inductors of FIG. 2B.

FIG. 4 is a diagram illustrating further details of the inductors of FIG. 2A.

FIGS. 5A-B are diagrams illustrating further details of the inductors of FIG. 2A.

FIG. 6 is a plan view illustrating an exemplary buck converter integrated circuit.

FIG. 7A is a block diagram illustrating control features of the exemplary IVR of FIG. 1.

FIG. 7B is a block diagram illustrating an exemplary non-linear control loop.

FIG. 8 is a plan view illustrating an exemplary IVR chip stack.

FIGS. 9A-D each are a plan view illustrating an exemplary interposer.

FIG. 10 is a diagram illustrating further details of the exemplary inductors of FIG. 2A.

FIG. 11 is a diagram illustrating further details of the exemplary IVR of FIG. 7A.

FIG. 12 is a diagram illustrating further details of the exemplary IVR of FIG. 7A.

FIG. 13 is a diagram illustrating further details of the exemplary IVR of FIG. 7A.

FIG. 14 is a diagram illustrating further details of the exemplary IVR of FIG. 7A.

FIGS. 15A-B are diagrams illustrating further details of the exemplary IVR of FIG. 7A.

FIG. 16 is a diagram illustrating further details of the exemplary IVR of FIG. 7A.

FIG. 17 is a diagram illustrating further details of the exemplary IVR of FIG. 7A.

FIG. 18 is a diagram illustrating further details of the exemplary IVR of FIG. 7A.

### DETAILED DESCRIPTION

One aspect of the disclosed subject matter relates to systems and methods for integrated voltage regulators, including a multi-chip module (MCM) having a voltage regulator formed on an interposer coupled to an integrated circuit (IC). The disclosed subject matter can be used, for a variety of applications, for example and without limitation, as a multi-chip module (MCM) having an integrated circuit and a DC-DC voltage regulator as described herein.

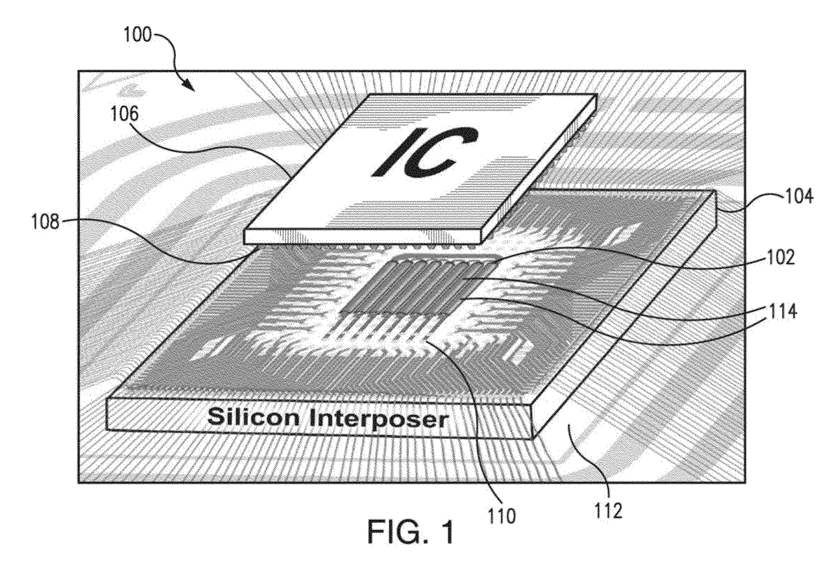

FIG. 1 illustrates an exemplary switched-inductor IVR for power conversion using thin-film magnetic power inductors. The IVR 102 can be integrated with an interposer 104 coupled to a substrate 112, with the IVR 102 being coupled to one or more vias 110 on the interposer 104. A CMOS integrated circuit 106 including one or more connecters 108 is aligned with and disposed on or near the one or more vias 110 to electrically couple the interposer 104 to the integrated circuit 106. The resulting multi-chip module 100, as embodied herein, can be formed by 2.5D chip stacking according to the disclosed subject matter.

An exemplary switched-inductor IVR can include inductors 114 that deliver both high current density and high effective inductor efficiency, as described further herein. Surface mount technology (SMT) air-core inductors can provide a current density up to 1.7 A/mm². Integrated magnetic-core power inductors can be highly scalable and can provide current densities as high as 8 A/mm². Such inductors can be included in IVRs by on-chip integration and chip stacking, as described here. Further details of exemplary power inductors are described in International Patent Application Publication No. WO 2012/166877, which is incorporated by reference herein in its entirety.

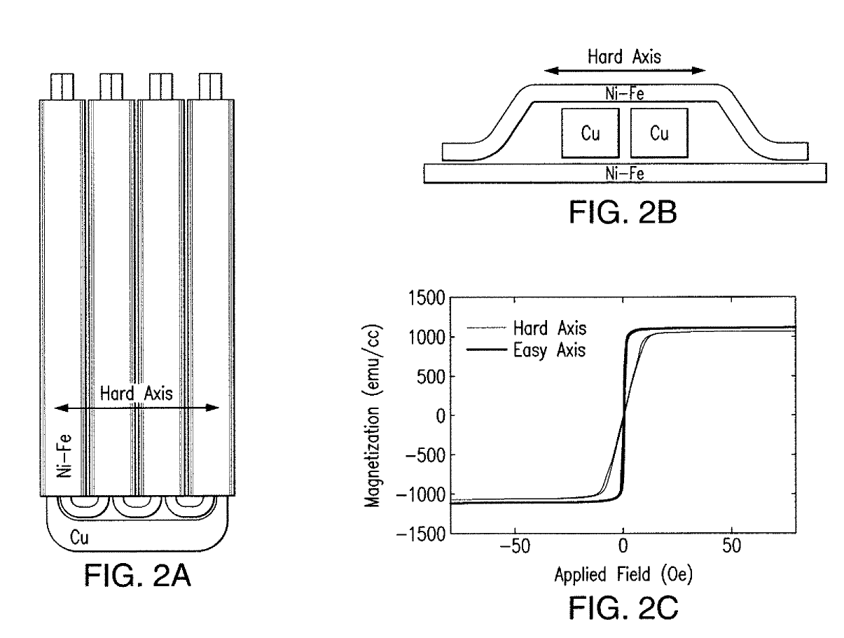

A power inductor topology, as embodied herein, can include an elongated spiral inductor having two layers of high permeability magnetic material forming a cladding around the copper conductor, as shown for example in FIG. 2A-C. As such, the inductance of the device can be increased. Such a configuration can have improved inductance density and quality factor at certain frequencies. Magnetic cladding of the inductor can be anisotropic. As such, the so-called hard axis of magnetization, which can exhibits a relatively linear relationship between an applied magnetic field and magnetization, can be configured to have the same orientation as the induced magnetic field from the elongated dimension of the inductor.

FIGS. 2A-C illustrate an exemplary arrangement of four inductors. Each inductor can be coupled with inductors on either side thereof through the magnetic cladding. An outer inductor can wrap around to symmetrically couple each inductor with a neighboring inductor. The inductors can be driven by a buck converter such that the DC currents through the windings within a magnetic cladding can travel in opposite directions, which can allow for inverse coupling. Inverse coupling can be utilized to avoid magnetic saturation in the cladding, which can improve current densities achieved. For example, in a multi-phase buck converter, as embodied herein, the DC current through each of the inductors can be balanced such that the DC magnetic field from adjacent windings can be equal and opposite, which can cancel the DC field in the magnetic cladding. Inverse coupling can also reduce inductor current ripple and improves transient response, and can improve current density. In an exemplary embodiment, and as embodied herein, the inductors can be fabricated on 200 mm silicon wafers. The bottom and top inductor yokes can be electroplated galvanostatically in a paddle cell. Physical vapor deposited (PVD) Ni₈₀Fe₂₀ films, embodied herein with a 65 nm thickness, and in some embodiments within a range of 10 nm to 200 nm, can be utilized as the electroplating seed layers. A bias magnetic field can be applied during seed layer deposition to produce magnetic anisotropy. The magnetic yokes can be plated through photoresist-defined molds, for example and without limitation, using thru-mask plating. In this manner, yoke edges can be suitably smooth to avoid the nucleation of magnetic domains and pinning of domain walls. Furthermore, the field around the yokes can also be plated to provide improved yoke deposit thickness and composition uniformity, and a thin resist frame can separate the plated regions. During plating, a dc magnetic field can be applied along the longest axis to define the magnetic anisotropy of the yokes. The magnetic field material can allow for continuous magnetic flux across the whole wafer, which can improve magnetic anisotropy.

The resist mask can be stripped, and the plated field and seed layer can etched. A bilayer of PECVD SiNx and TEOS dielectric, which as embodied herein, can be 1 μm in total thickness, and in some embodiments within a range of 0.5 μm to 2 μm, can be used to encapsulate the yokes. With top and bottom yokes being fabricated, magnetic vias can be opened where the top and bottom yokes contact, for example by reactive ion etching (RIE). Copper coils can be electroplated through resist masks, for example and as embodied herein to a thickness of 5 μm, and in some embodiments within a range of 1 μm to 10 μm. A photoresist (for example, AZ Electronics P4620), for example and as embodied herein having a thickness of 6 μm, and in some embodiments within a range of 2 μm to 10 μm, can be used to encapsulate the coils. The photoresist can be reflowed, for example at a temperature of 120° C., and in some embodiments within a range of 100° C. to 150° C., to give sloped sidewalls, which can gradually extended the top yokes to the magnetic via to avoid the formation of an abrupt angle, which can saturate or pin domain walls. The resulting photoresist can be hard-baked, e.g., at 200° C. for 2 hours, and in some embodiments within a temperature range of 180° C. to 220° C. for I to 3 hours, to form a rigid encapsulant. Such hard-baked photoresist structures can exhibit relatively smooth and partially planar surfaces in advance of top yoke plating.

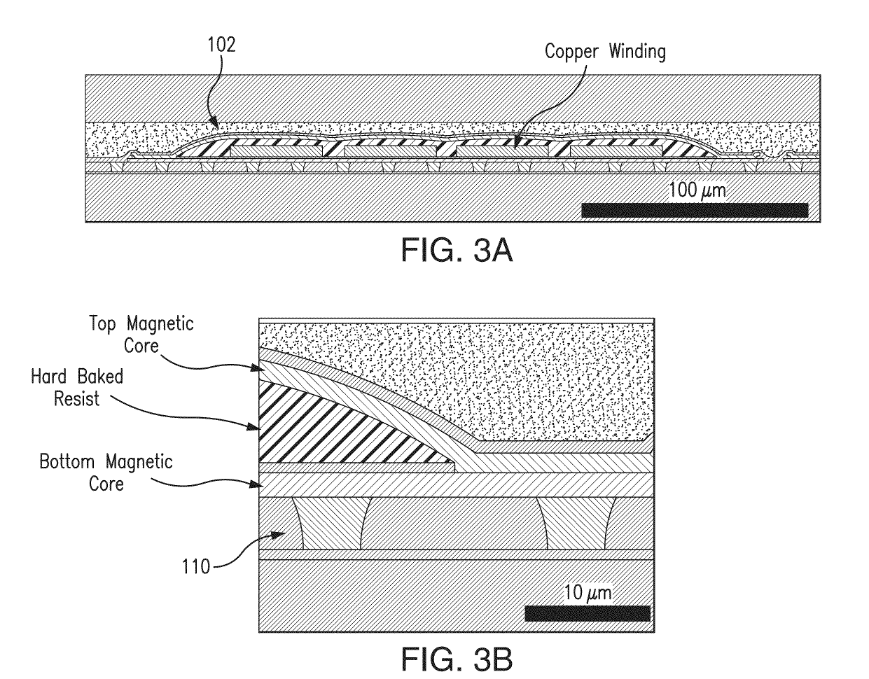

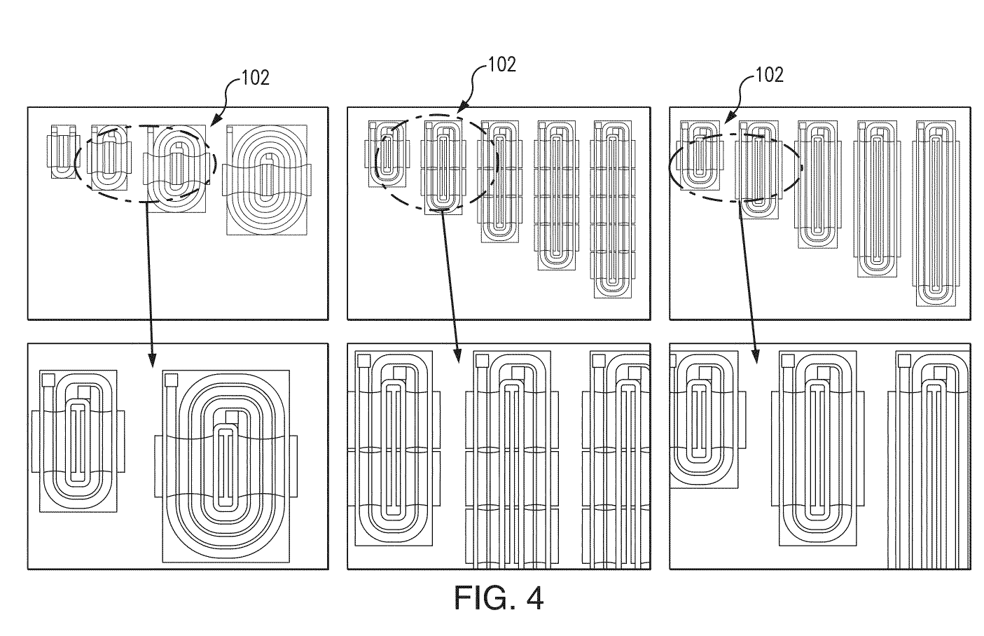

Furthermore, electrical contacts, such as copper pads, can be opened, for example and as embodied herein using RIE. FIGS. 3A-B each shows a cross-section of a single-turn inductor 102 and a magnetic via 110. FIG. 4 shows several non-coupled inductors 102 fabricated according to the disclosed subject matter.

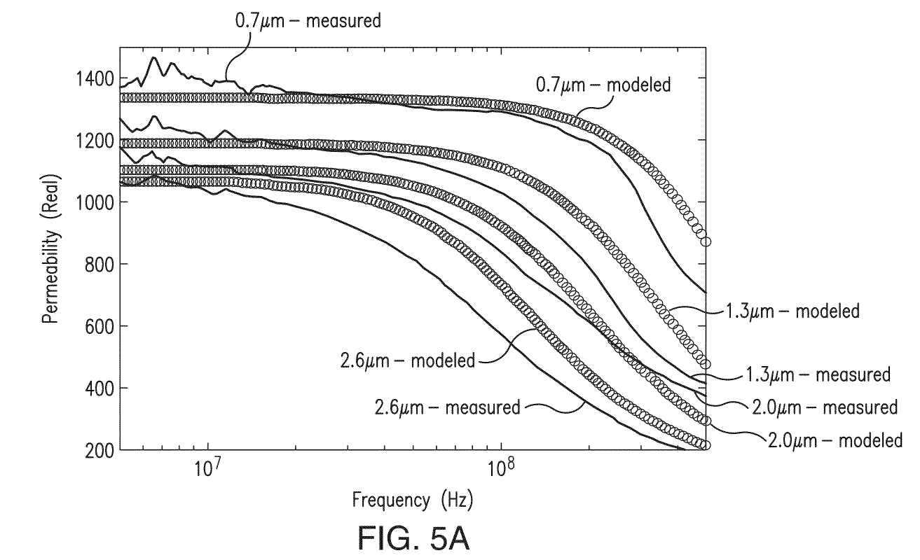

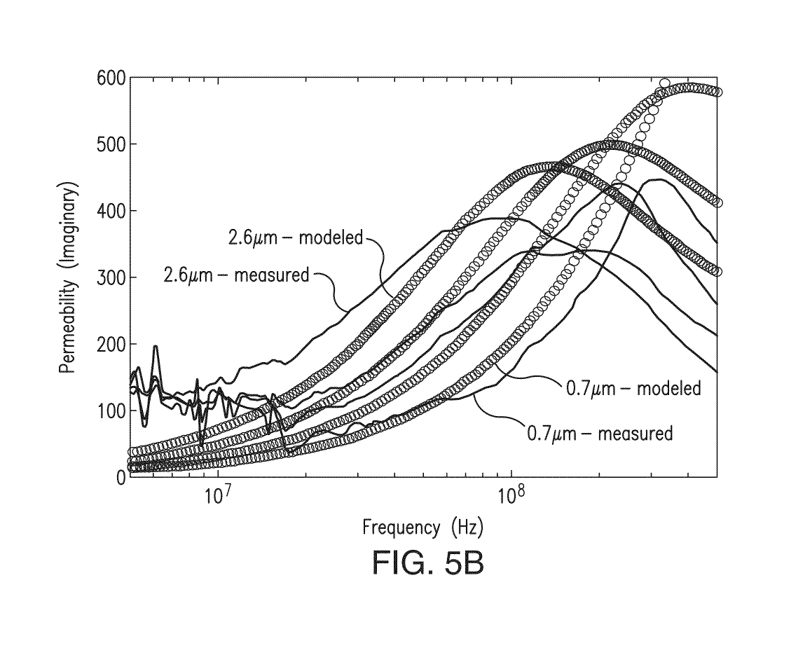

The resistivity of the electroplated Ni₄₅Fe₅₅ was measured to be 45 μΩ·cm using a four-point probe method, which, for purpose of comparison, is double the resistivity of Permalloy (Ni₈₁Fe₁₉). The improved resistivity can reduce eddy current at high frequencies. As shown in FIG. 2C, magnetic hysteresis loops can be obtained using a vibrating sample magnetometer (VSM) with a plated Ni₄₅Fe₅₅ film having a thickness of 2.0 μm, as embodied herein. The film can have anisotropy with a relatively low coercivity, 0.2 Oe, along both the easy and hard axes. Saturation magnetization and anisotropy fields can be 1.5 T and 13 Oe, respectively. Resulting permeability spectra can be obtained by measuring the impedance of a single-stripe loop fixture provided with magnetic films. FIGS. 5A and 5B shows real and complex permeability spectra, respectively, of plated Ni₄₅Fe₅₅ films with different thicknesses. For purpose of comparison, theoretical permeability spectra are also shown in the circle lines. As shown, the low frequency permeability can achieve a value of 1300 for the 0.7 μm films. As the thickness of the film increases, the value decreases to 1000 for the 2.6 μm film, which can be due at least in part to the shape anisotropy induced in the thicker films. Furthermore, due at least in part to eddy current and skin effects, the roll-off frequency decreases from 200 MHz to 50 MHz as the thickness increases.

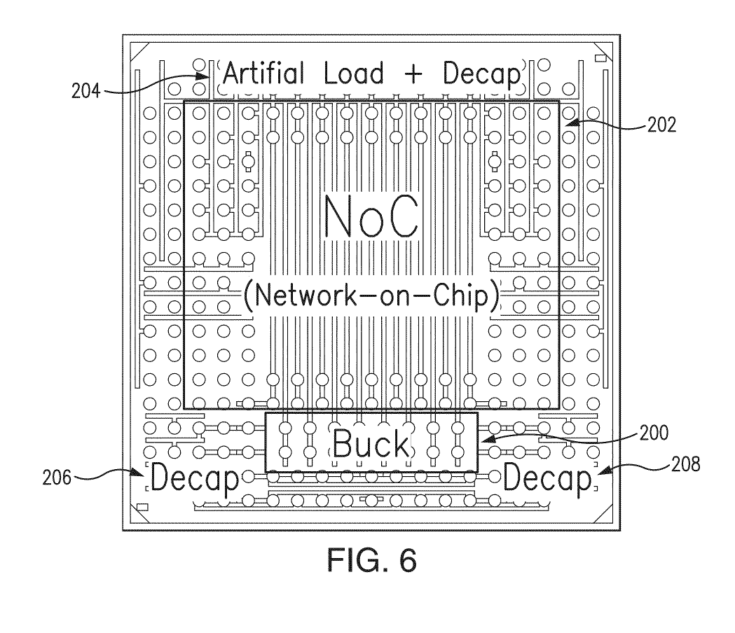

According to one aspect of the disclosed subject matter, an eight-phase buck converter is provided. The buck converter can drive the magnetic core power inductors. A controller can be configured to accommodate any number of inductor phases, for example and as embodied herein with eight phases, and can have variations in inductance values and coupling strengths. A buck converter IC can be fabricated, for example and as embodied herein, using 45 nm SOI technology from IBM. FIG. 6 illustrates an exemplary buck converter IC 200, a network-on-chip 202 acting as an on-chip load, a further load 204 used to characterize the buck converter, and input and output decoupling capacitance 206, 208. Within the buck converter, as embodied herein, control circuitry occupies 0.178 mm², while bridge FETs occupy 0.1 mm². The bridge FETs can be configured as thick-oxide devices, and can withstand a V_{ds} of up to 1.8 V. 48 nF of deep-trench (DT) and thick oxide MOS capacitance, and in some embodiments between 5 nF to 100 nF, can decouple V_{OUT}, as embodied herein having an area of 0.40 mm², and 21 nF (+/−1 nF) of DT with an area of 0.52 mm² can decouple the 1.8V input supply to compensate for PDN impedance, which can be due at least in part to the wirebond connections.

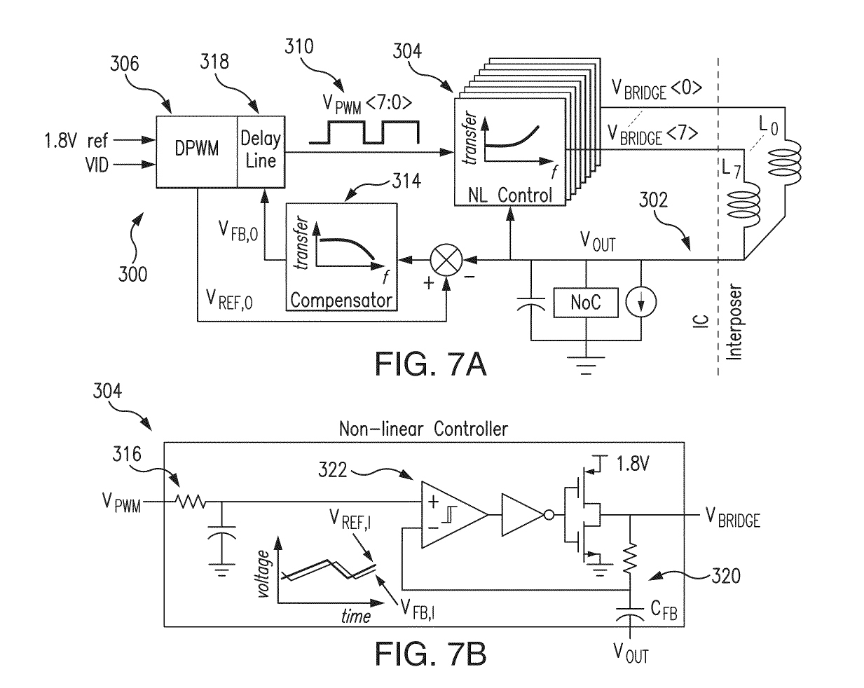

FIG. 7A shows a system level diagram illustrating control features of the exemplary IVR according to the disclosed subject matter. The buck converter control circuitry 300 can be disposed on the IC, and can include two control loops, a slow voltage-mode outer loop 302 to provide low-frequency regulation and a fast inner loop 304 to respond to high-frequency load transients. A digital pulse-width modulator (DPWM) 306 can receive an eight-bit voltage identifier code (VID), from which up to eight pulse-width modulation (PWM) signals 310 can be derived with programmable switching frequency, fₛ, and phase relationships. The resolution of the DPWM 306 can correspond to the 250-ps period of a high-frequency reference clock provided by an on-chip PLL. The DPWM 306 can also generate an analog reference voltage, V_{REF}, of 1.8V for the outer feedback loop 302. The compensator 314 for the outer feedback loop 302 can be embodied as a low-pass filter with programmable pole frequency, and can be chosen, for example based on the resulting inductance value, to be 10 to 16 times lower than the effective switching frequency Nfₛ, where N represents the number of phases in operation. The outer feedback voltage, V_{FB,O}, can drive a delay line 318 that modulates the DPWM 306 output to create the reference PWM signal, V_{PWM}, which drives the fast non-linear inner control block 304.

FIG. 7B illustrates an exemplary fast inner loop 304. As embodied herein, signal V_{PWM} can drive an RC filter 316 to generate the inner reference voltage, V_{REF,1}, while the bridge output voltage for each phase, V_{BRIDGE}, can drive another RC filter 320 to generate the inner feedback voltage, V_{FB,1}. The pole in both RC low-pass filters can be configured to be below fₛ, and as such the steady state amplitude of V_{REF,1} and V_{FB,1} can be around 150 mV, which can allow for a small signal feedback gain of ˜30 V/V and relatively stable loop dynamics. In steady state, V_{FB,1} can slew behind V_{REF,1} and the resultant evaluation of the comparator 322 causes V_{BRIDGE} to track V_{PWM}. In the event of a large load current transient, an error in the output voltage, V_{OUT}, can couple across C_{FB} onto V_{FB,1}, and the comparator 322 can react to reduce overshoot in V_{OUT}. As such, the fast non-linear response can reduce the required decoupling capacitance on the output voltage V_{FB,1}.

The IC can further include a 64-tile network-on-chip (NoC) having four parallel, heterogeneous, physical network planes with independent frequency domains. The NoC can provide a highly scalable platform configured for granular power distributions in which traffic patterns can be used to modulate load currents and transients. NoCs can be utilized, for example, as a basic interconnect infrastructure for complex SoCs. For purpose of communication in the SoCs, for improved energy and performance in NoCs, a separate voltage-clock domain can be reserved for the NoC alone. The NoC can provide realistic load behavior and support experimentation on supply noise and DVFS. Furthermore, an artificial load on the IC can generate relatively large current transients, for example within a range of 0.01 A to 5 A, with 0.02 A/ps slew for characterization of the feedback controller.

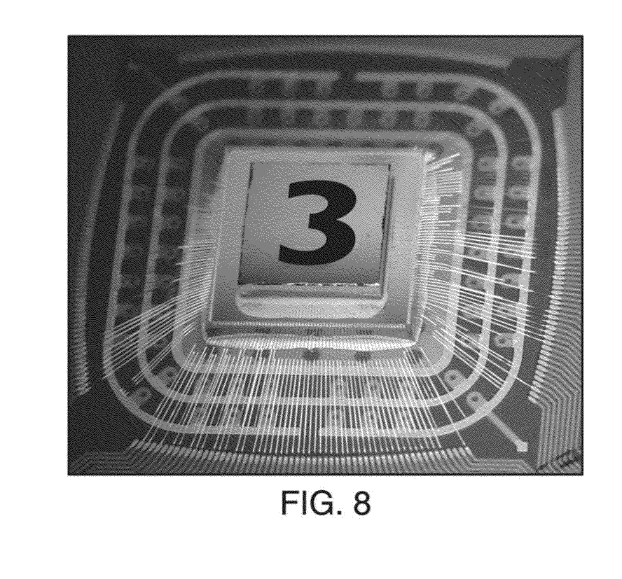

According to another aspect of the disclosed subject matter, FIG. 8 shows an exemplary 2.5D chip stack. As shown, the buck converter IC can be flip-chip attached to the silicon interposer, which can hold the coupled power inductors while breaking out signals and the 1.8 V input power supply to wirebond pads on the perimeter of the interposer. The signal and power nets can wirebonded to a BGA laminate, which can be placed in a socket for electrical test. The bridge FETs on the IC can drive current from the 1.8V input supply through the inductors on the interposer. The current can pass through the inductors and back into the IC through C4 bumps, and can be distributed to the load across the on-chip power distribution network.

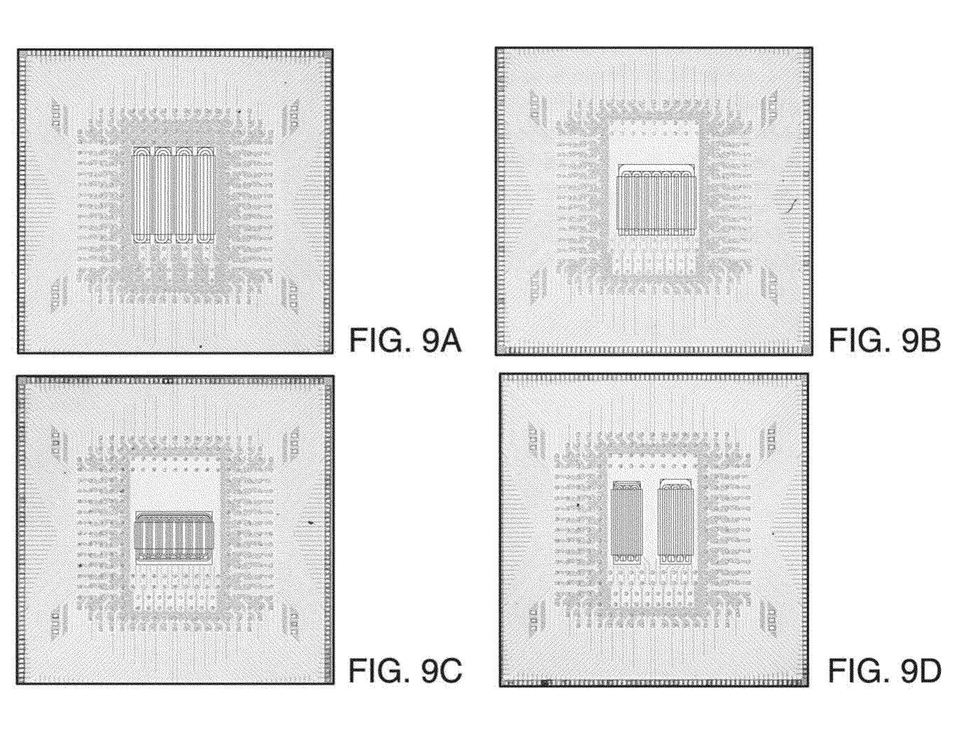

FIGS. 9A-D each illustrates an exemplary power inductor fabricated on the silicon interposer. FIG. 9A shows an exemplary power inductor having four uncoupled two-turn inductors (type 1). FIG. 9B shows an exemplary power inductor having eight single-turn coupled inductors (type 2). FIG. 9B shows an exemplary power inductor having eight two-turn coupled inductors (type 3). FIG. 9D an exemplary power inductor having two sets of four single-turn coupled inductors (type 4). The C4 footprint of the exemplary IC can be configured to have an area of 3.2 mm² in the center of the interposer for the inductors, although the inductors can utilize less than the available area.

As embodied herein, the power inductors are not integrated in the front-end-of-line (FEOL) of the CMOS technology, and thus the area of these devices can be reduced. As such, the inductor area in a chip stacking integration scheme can be determined by the scalability of the IVR solution, rather than the area consumed by the power inductors. The current density of a candidate inductor topology can match or exceed the current density of the load. As such, the inductor can reside within the perimeter of the load, and, for example in the case of a multi-core architecture, can provide improved scalability, for example where multiple cores can be stamped across the load IC with a corresponding set of inductors similarly stamped across the interposer. In some configurations, digital logic can consume current at levels up to 2 A/mm², which can be exceeded by power inductors according to the disclosed subject matter.

With 2.5D chip stacking, the power delivery network (PDN) can have a relatively large impedance. The combined impedance in the PDN from the socket, package, wirebonds, and interposer traces can be 70 mΩ at DC, and can increase with frequency due at least in part to the inductance of the wirebonds and other traces. The resistive losses from the PDN can reduce performance of the system, and the high frequency impedance can impairs the ability of the voltage regulator to suppress voltage droop during load current transients. As such, a 3D integration technique that incorporates thru-silicon-vias (TSVs) in the interposer can be implemented for high current applications to reduce PDN impedance.

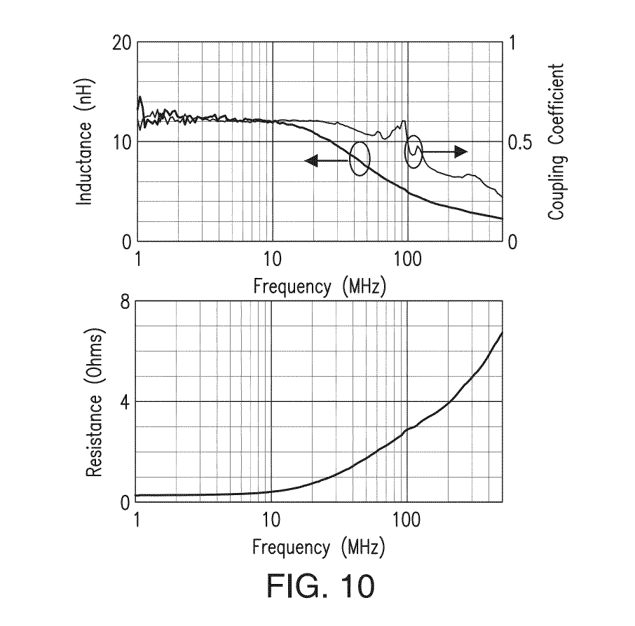

For purpose of illustration, the inductance, coupling coefficient and resistance of a single turn, 1200 μm inductor with 2 μm thick magnetic layers is shown in FIG. 10. FIG. 10 illustrates the performance of the coupled, single-turn inductors fabricated on the interposer. The DC inductance of 12.5 nH shown in FIG. 10 can be suitable for integrated power conversion. Eddy currents induced in the magnetic core starting in the 10-100 MHz range can cause the inductance and coupling to be reduced. Eddy currents in the core, as well as the winding skin depth and proximity effect, can result in an increase in the winding resistance over the same switching frequency. The performance is consistent with the measurements of permeability shown in FIG. 5, and can be improved with the addition of insulating laminations in the magnetic core to suppress eddy currents.

### EXAMPLE

An exemplary 2.5D IVR chip stack was assembled and tested to verify functionality. In all DC measurements, the resistive losses from the PDN were excluded, and the input voltage was compensated such that the input voltage at the IC is 1.8 V. All measurements were conducted with the silicon interposer carrying eight single-turn coupled inductors, unless otherwise noted.

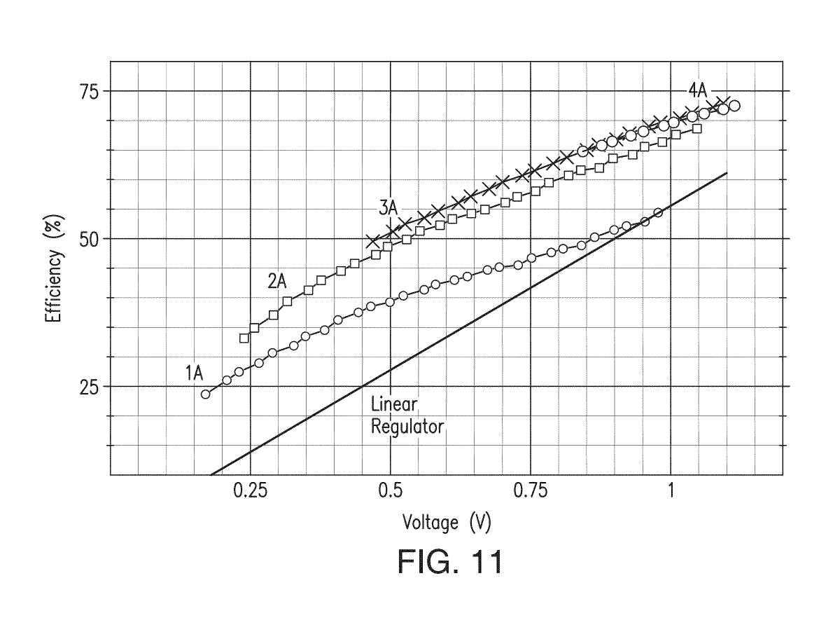

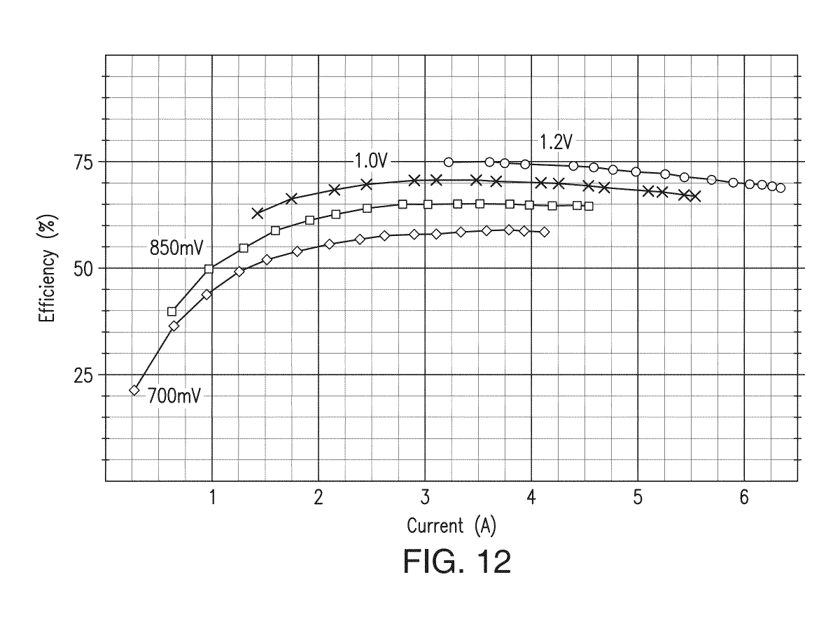

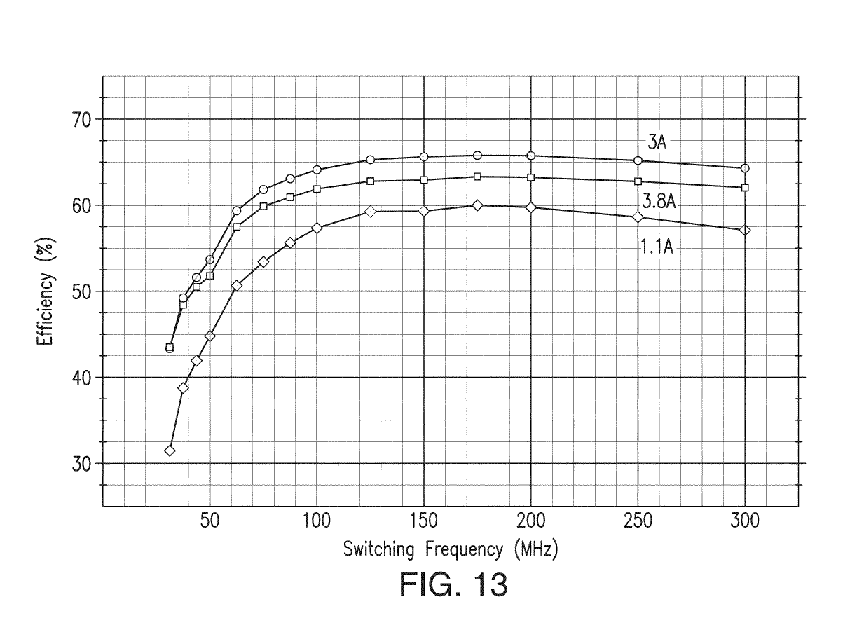

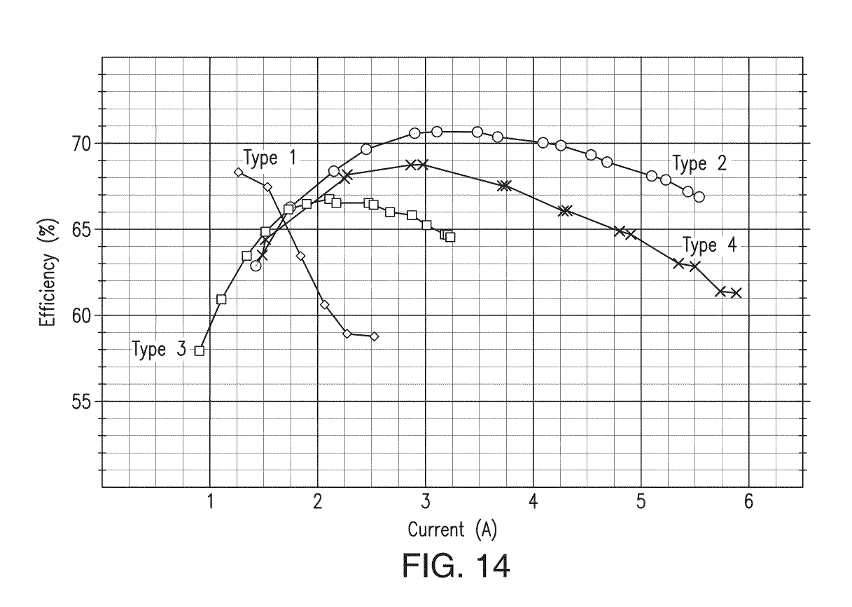

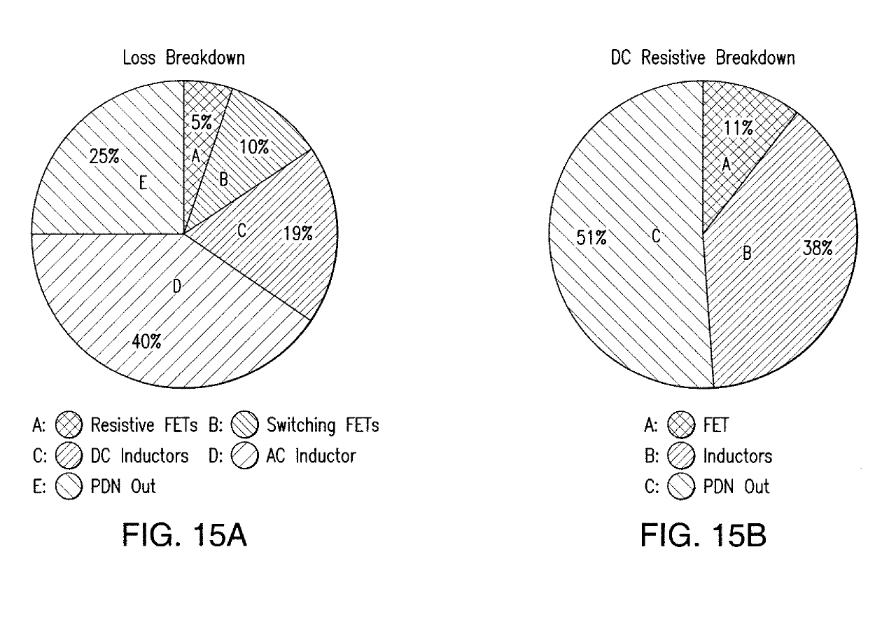

The efficiency as a function of output voltage and load current for the IVR is shown in FIGS. 11 and 12. The efficiency is shown to reach 75% with output voltage of 1.2V and load current of 3.2 A. The efficiency at 1 V is 71% when the load current is 3 A. The load current measured for the IVR reaches 6.3 A, which can be limited at least in part by the on-chip load. FIG. 13 shows the efficiency of IVR when operated at various switching frequencies and load currents. The desired switching frequency for the IVR is in the range of 125 to 200 MHz. FIG. 14 shows the efficiency as a function of load current for each of the four inductor embodiments, where the eight single-turn coupled inductors configuration (type 2) is shown to have the highest efficiency. A breakdown of the IVR losses is shown in FIG. 15A-B for an IVR having a 1 V output voltage and 3 A load current. In this configuration, approximately 40% of the inefficiency is due to high-frequency losses in the inductor, which can be attributed at least in part to the formation of eddy currents in the magnetic core, as discussed further below.

Another source of loss can be the on-chip power distribution network resistance, as described herein. The IVR according to the disclosed subject matter can be configured to act as a flexible platform for testing various power inductor topologies. Therefore, in the case of the power distribution network, certain design features can be compromised for flexibility. As embodied herein, once the load current passes through the inductors, the current enters the on-chip power distribution network through C4 bumps near the buck converter. The load current can travel across the on-chip power distribution network (for example, 3 mm) to the artificial load, where the output voltage can be measured. The on-chip power distribution network resistance of 45 mΩ can account for 25% of the converters losses. Additional conversion loss can be attributed to the DC resistance of the inductors and the switching and resistive losses of the bridge FETs.

The IVR embodiment having eight single-turn coupled inductors (type 2) can down convert with a high efficiency at a load current of 3 A, and can achieve a current of 6.3 A or more. The inductors can occupy an area of 1.96 mm². Current density for the IVR at a high efficiency was measured to be 1.53 A/mm², and the current density was measured to be up to 3.21 A/mm². The FEOL area occupied by the buck converter, controller, bridge FETs and some input decoupling capacitance can be 0.278 mm². At a high efficiency, therefore, the FEOL current density for the exemplary IVR can be 10.8 A/mm², while the current density can be up to 22.7 A/mm². In this example, the area of some input decoupling capacitance was excluded, as this capacitance would not necessarily be utilized in a fully 3D integration approach, where the PDN impedance can be lower.

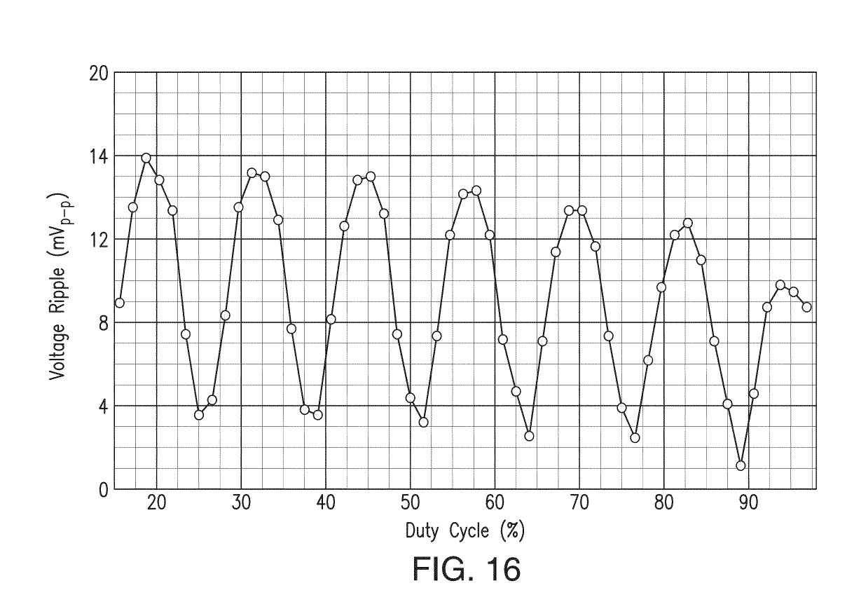

FIG. 16 shows the output voltage ripple from the exemplary IVR as a function of duty cycle with the buck converter operating at a switching frequency of 100 MHz. A S high voltage ripple is shown to be 14 mV peak-to-peak, occurring when 1/16=mod(D,⅛), where D represents the duty cycle. A high voltage ripple of 3 mV peak-to-peak occurs when 0=mod(D, ⅛), when the inductor current ripple from each of the eight phases effectively cancel each other. The IVR voltage ripple can be improved as insulating laminations are added to the magnetic yoke of the inductors, thereby improving high frequency inductance.

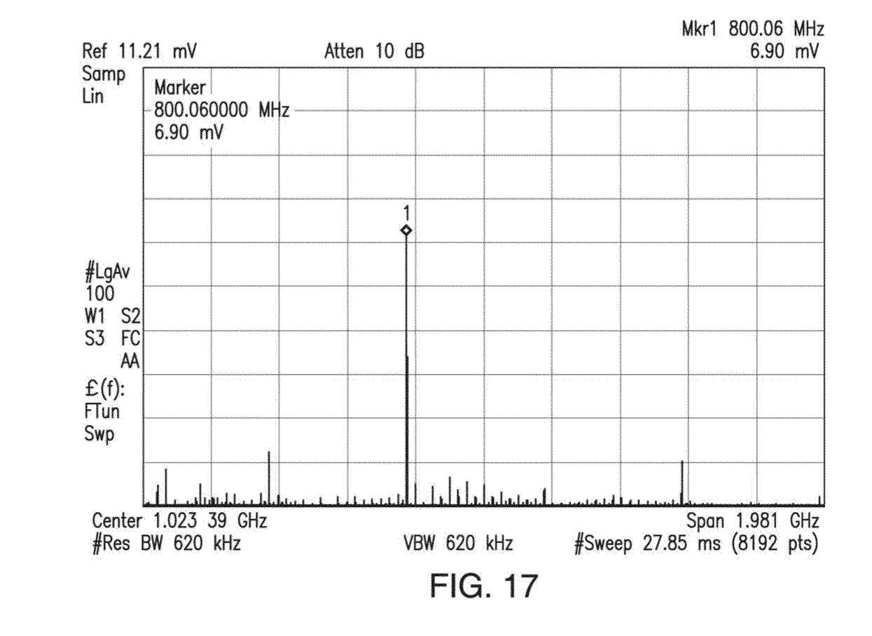

FIG. 17 shows the frequency spectrum of the output voltage with the buck converter switching at 100 MHz. As shown, the highest component of the output voltage occurs at 800 MHz, which represents the eighth harmonic of the switching frequency. The lower spectral content at other harmonics of the switching frequency can indicate that the current through each of the eight inductors is suitably balanced. As such, asymmetry in the inductor design, due at least in part from having the outside inductor phase wrap around, as shown in FIG. 2, can have negligible impact on the inductor current balance.

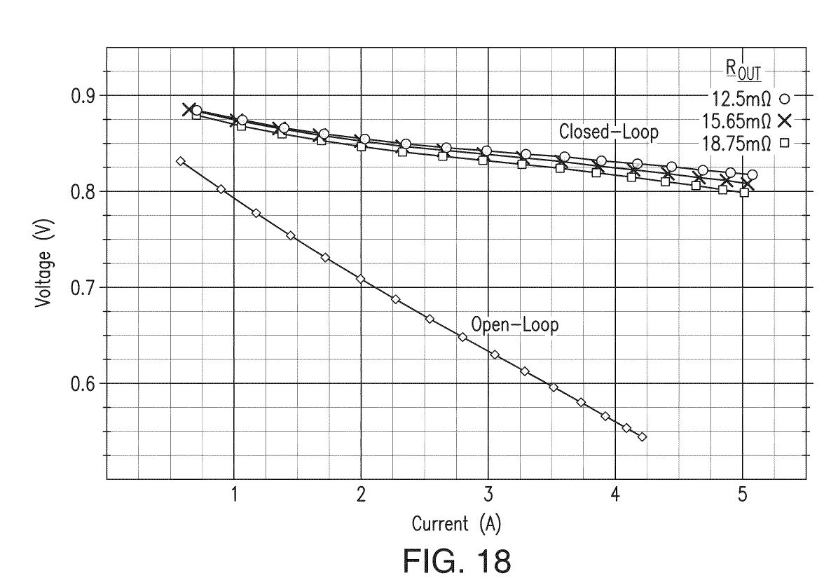

The impedance of the input PDN can reduce the ability of the feedback controller to suppress load current transients, as the input power supply decreases. However, as shown in FIG. 18, which illustrates the load-line regulation capability of the outer voltage-mode feedback loop, the closed loop output impedance can be reduced with respect to the open loop output impedance. The gain of the error amplifier in the outer feedback loop can be increased to reduce the closed loop output impedance of the TVR.

The foregoing merely illustrates the principles of the disclosed subject matter. Various modifications and alterations to the described embodiments will be apparent to those skilled in the art in view of the teachings herein. For example, various values and ranges, including dimensions, electronmagnetic properties, temperatures and times, are provided in the descriptions of the exemplary embodiments, and a person skilled in the art will be able to modify the values and ranges for use in particular applications within the scope of the disclosed subject matter. It will be appreciated that those skilled in the art will be able to devise numerous modifications which, although not explicitly described herein, embody its principles and are thus within its spirit and scope.

1. A multi-chip module (MCM) comprising:
a packaging substrate;
an interposer coupled to the substrate, the interposer comprising a voltage regulator coupled to one or more vias; and
a CMOS integrated circuit comprising one or more connecters aligned with and disposed proximate to the one or more vias to thereby electrically couple the interposer to the integrated circuit.

2. The MCM of claim 1, wherein the interposer comprises silicon.

3. The MCM of claim 1, wherein the voltage regulator comprises one or more inductors.

4. The MCM of claim 3, wherein the one or more inductors comprises a plurality of inductors, each inductor coupled to one or more inductors proximate thereto.

5. The MCM of claim 4, wherein the plurality of inductors comprises an outer inductor joining a first end inductor to a second end inductor to symmetrically couple each inductor with a pair of neighboring inductors.

6. The MCM of claim 3, wherein the one or more inductors comprises four uncoupled two-turn inductors.

7. The MCM of claim 3, wherein the one or more inductors comprises eight single-turn coupled inductors.

8. The MCM of claim 3, wherein the one or more inductors comprises eight two-turn coupled inductors.

9. The MCM of claim 3, wherein one or more inductors comprises two sets of four single-turn coupled inductors.

10. The MCM of claim 3, wherein the voltage regulator comprises a buck converter coupled to the one or more inductors and configured to inversely couple the one or more inductors.

11. The MCM of claim 3, wherein the buck converter comprises a multi-phase buck converter, the MCM further comprising a power controller configured to provide power from the buck converter at a different phase corresponding to each of the one or more inductors.

12. A method of forming a voltage regulator on an interposer of a multi-chip module (MCM) comprising:
depositing on the interposer a magnetic alloy under a magnetic biasing field to form a plurality of magnetic cores including a top core and a bottom core;
inverse coupling adjacent magnetic cores of the plurality of magnetic cores;
forming copper windings about each of the plurality of magnetic cores;
forming one or more electrodes on the top magnetic core and on the bottom magnetic core;
electrically isolating the copper windings from the bottom magnetic core using a layer of barrier material;
electrically isolating the copper windings from the top magnetic core using a resist process;
joining the electrodes of bottom magnetic core and the top magnetic core to one or more respective pads on the interposer; and
forming vias through the interposer proximate the one or more pads.

13. The method of claim 12, further comprising wrapping an outer core around a first end magnetic core and a second end magnetic core to symmetrically couple each magnetic core with a pair of neighboring magnetic cores.

14. The method of claim 12, further comprising depositing top and bottom yokes corresponding to each magnetic core by electroplating.

15. The method of claim 14, wherein depositing the top and bottom yokes comprises plating the top and bottom yokes through photoresist-defined molds by through-mask plating.

16. The method of claim 15, further comprising
plating an area around each of the top and bottom yokes, and
separating each plated area with a resist frame.

17. The method of claim 15, wherein plating the top and bottom yokes comprises applying a magnetic field along an axis of the top and bottom yokes to define a magnetic anisotropy of the top and bottom yokes.

18. The method of claim 14, further comprising encapsulating the top and bottom yokes with a layer of dielectric material.

19. The method of claim 14, wherein forming the vias comprises opening a portion of the interposer proximate a point of contact of each top yoke with a corresponding bottom yoke by reactive ion etching.

20. The method of claim 12, wherein forming the copper windings comprises electroplating the copper windings through a resist mask.
